(19) United States
(12) Patent Application Publication
(10) Pub. No.: US 2007/0037408 A1
(43) Pub. Date: Feb. 15, 2007

(54) Method and apparatus for plasma processing

(75) Inventors: Kunihide Tachibana, Kyoto (JP); Ryouji Inoue, Simane (JP)

Correspondence Address: LOWE HAUPTMAN BERNER, LLP, 1700 DIAGONAL ROAD, SUITE 300, ALEXANDRIA, VA, 22314, US

(73) Assignee: HITACHI METALS, LTD., Tokyo (JP)

(21) Appl. No.: 11/200,035

(22) Filed: Aug. 10, 2005

(51) Int. Cl. H01L 21/469; C23C 16/00

(52) U.S. Cl. 438/778; 438/785; 438/798; 118/715

(57) ABSTRACT

A plasma processing method using an apparatus including an electrode unit configured by providing a dielectric layer on a surface of a metal substrate having a surface defining a plurality of through holes and by superimposing a plurality of the metal substrates so that the through holes coincide, the method comprising: a gas supply step of supplying a predetermined gas at a pressure near an atmospheric pressure into the through holes; a voltage application step of applying a voltage between the metal substrates to transform the gas within the through holes into a plasma; and a processing step of processing a target member arranged near the electrode unit to face the electrode unit.

### CROSS-REFERENCE TO RELATED APPLICATIONS

The entire contents of which the prior Japanese Patent Application No. 2003-16106 filed on Jan. 24, 2003 are incorporated herein by reference.

### BACKGROUND OF THE INVENTION

1) Field of the Invention

The present invention relates to a method and an apparatus for plasma processing.

2) Description of the Related Art

Conventionally, as methods for plasma processing, a DC glow discharge plasma processing method for applying a DC voltage between parallel electrodes arranged in a reaction chamber at a relatively high degree of vacuum of 13 pascals to 1.3 kilopascals, and a high frequency glow discharge plasma processing method for applying a high frequency power to a coil arranged outside of a reaction chamber have been mainly used. However, since the processing at the high degree of vacuum is low in productivity and high in equipment cost, use of many methods for plasma processing at a pressure near an atmospheric pressure has been recently reported instead.

For example, Japanese Patent Application Laid-Open No. 63-50478 entitled “Method for forming thin film” (hereinafter, “Patent Literature 1”) discloses a method for depositing a C film by performing a plasma processing between an electrode and a counter electrode by a high frequency power supply using He gas which tends to make a glow discharge stable even at the atmospheric pressure. Japanese Patent Application Laid-Open No. 2-73978 entitled “Method for forming thin film” (hereinafter, “Patent Literature 2”) discloses a method for enlarging a range of a glow discharge and thereby making it possible to process a processing target member having a high area by interposing a resistor having a high resistance between the electrodes disclosed in the Patent Literature 1.

Furthermore, Japanese Patent Application Laid-Open No. 3-193880 entitled “Method and apparatus for forming film at high rate by microwave plasma CVD at high pressure” (hereinafter, “Patent Literature 3”) discloses a method for depositing a thin film by introducing a microwave into a reaction chamber and generating a microwave plasma at the atmospheric pressure. Japanese Patent Application Laid-Open No. 8-209353 entitled “Plasma processing apparatus and method therefor” (hereinafter, “Patent Literature 4”) discloses a method for depositing a thin film by concentrating an electric field on a plurality of protruding electrodes and generating a plasma discharge at the atmospheric pressure by a unipolar discharge.

Furthermore, Japanese Patent Application Laid-Open No. 9-104985 entitled “Method and apparatus for forming film at high rate using rotary electrode” (hereinafter, “Patent Literature 5”) discloses a method for depositing a thin film by generating a voltage between a rotary electrode and a counter rotary electrode and generating a plasma discharge at the atmospheric pressure. Japanese Patent Application Laid-Open No. 10-154598 entitled “Method and apparatus for glow discharge plasma processing” (hereinafter, “Patent Literature 6”) discloses a method for maintaining a stable glow discharge by arranging a dielectric between an electrode and a counter electrode, applying a pulsed electric field between the electrodes, and stopping a discharge before the discharge is changed to an arc discharge.

The conventional techniques have, however, the following disadvantages. With the techniques disclosed in the Patent Literatures 1 to 6, the inventors of the present invention discovered that when a processing target member is a conductor such as metal, it is practically difficult to form a stable glow discharge plasma at the pressure near the atmospheric pressure and to perform a wide-range surface treatment or film deposition on an entire surface of the processing target member.

### SUMMARY OF THE INVENTION

It is an object of the present invention to solve at least the problems in the conventional technology.

A plasma processing method according to one aspect of the present invention using an apparatus including an electrode unit configured by providing a dielectric layer on a surface of a metal substrate having a plurality of through holes and by superimposing a plurality of the metal substrates so that the through holes coincide, the method includes: a gas supply step of supplying a predetermined gas at a pressure near an atmospheric pressure into the through holes; a voltage application step of applying a voltage between the metal substrates to transform the gas within the through holes into a plasma; and a processing step of processing a processing target member arranged near the electrode unit to face the electrode unit.

A surface treatment gas may be supplied at the gas supply step so that the processing target member can be subjected to a surface treatment at the processing step.

Alternatively, a reactive gas may be supplied at the gas supply step so that the processing target member can be subjected to a film deposition at the processing step.

Preferably, the dielectric layer mainly consists of at least one oxide selected from a group consisting of SiO₂, Al₂O₃, MgO, ZrO₂, TiO₂, Y₂O₃, PbZrO₃—PbTiO₃, BaTiO₃, and ZnO.

Further, each of the metal substrates preferably consists of an Fe—Ni alloy containing 36% to 55% by mass of Ni.

An apparatus for plasma processing according to another aspect of the present invention includes: an electrode unit configured by providing a dielectric layer on a surface of a metal substrate having a plurality of through holes, and by superimposing a plurality of the metal substrates so that the through holes coincide with one another; a gas supply unit that supplies a surface treatment gas or a reactive gas to the through holes; and a voltage application unit that applies a voltage between the metal substrates.

Preferably, the dielectric layer mainly consists of at least one oxide selected from a group consisting of SiO₂, Al₂O₃, MgO, ZrO₂, TiO₂, Y₂O₃, PbZrO₃—PbTiO₃, BaTiO₃, and ZnO.

Further, each of the metal substrates preferably consists of an Fe—Ni alloy containing 36% to 55% by mass of Ni.

In the apparatus for plasma processing, at least three metal substrates may be superimposed, and the voltage application unit may be configured to apply a voltage between the both end metal substrates, and the apparatus further may include a third electrode control unit that applies a voltage for controlling a discharge in the through holes between the metal substrates, to the intermediate metal substrate.

As explained above, one of notable features of the present invention is that electrodes obtained by superimposing the metal substrates each having a plurality of through holes are used, and that by generating a dielectric barrier discharge on an end surface of each through hole of the metal substrates, a plasma is generated within each hole. It is thereby possible to process a processing target member having a large area.

Namely, according to the present invention, by integrating a plurality of micro discharges generated within the respective holes formed in the electrodes without using two separate electrodes facing with each other as used in the conventional techniques, it is possible to simultaneously process the processing target member having a large area (for example, a substrate having a large area).

Furthermore, when another metal substrate is inserted between the metal substrates that constitute the electrodes so as to work as a third electrode and a voltage applied to the third electrode is controlled, then the discharge voltage can be controlled to be reduced and the discharge can be controlled to be switched on and off. Besides, with this configuration, the discharge length itself can be increased, so that the plasma generation efficiency can be enhanced.

The metal substrate that constitutes each electrode is not limited to a flat substrate and the form of the metal substrate can be selected according to a surface shape of the processing target member. As shapes of the through holes, various shapes can be adopted, such as triangular, rectangular, hexagonal, circular, elliptic, gourd-shaped, and combinations thereof. The metal substrate is formed into a mesh by regularly arranging through holes. The metal substrate can be in the form of a honeycomb that is one type of the mesh or formed into slits using elongate rectangles. An optimum aspect ratio of a width of a metal part to a width of a hole part or a diameter can be appropriately set according to the usage. As the metal substrate, the metal substrate on which a solid-state dielectric layer is formed using a dielectric shown in the embodiment is employed.

The reaction chamber in which the electrode unit is arranged can have a degree of vacuum equal to that of an ordinary plasma process or can have a pressure near the atmospheric pressure. Namely, in the latter case, it can be regarded that the present invention provides a method or an apparatus for ambient pressure plasma processing. “To make the pressure of the reaction chamber equal to the pressure near the atmospheric pressure” means that the pressure of the reaction chamber of the plasma processing apparatus according to the present invention can be controlled only by a surface treatment gas or reactive gas supply unit and a simple vacuum pump.

The “processing target member” means a member subjected to the surface treatment or the film deposition. When the processing target member is a substrate, it can be also referred to as “processing target substrate”. The processing target member is not always stationary and can be moved at a constant speed.

Other objects, features, and advantages of the present invention will be apparent from the following explanations with reference to the accompanying drawings.

### BRIEF DESCRIPTION OF THE DRAWINGS

FIG. 1 is a schematic block diagram that depicts a plasma processing apparatus centering around a reaction chamber thereof according to one embodiment of the present invention;

FIG. 2 is a plan view of an example of an electrode employed in the plasma processing apparatus according to the embodiment;

FIG. 3 is a plan view of another example of an electrode employed in the plasma processing apparatus according to the embodiment;

FIG. 4 is a plan view of another example of an electrode employed in the plasma processing apparatus according to the embodiment;

FIG. 5 is a plan view of another example of an electrode employed in the plasma processing apparatus according to the embodiment;

FIG. 6 is a sectional view of an electrode unit of the plasma processing apparatus according to the embodiment;

FIG. 7 is a sectional view of the electrode unit when a third electrode is provided in the plasma processing apparatus according to this embodiment;

FIG. 8 is an explanatory diagram of a configuration example of the electrode unit relative to a curved processing target member; and

FIG. 9 is an explanatory diagram of a configuration example of the electrode unit relative to an irregular processing target member.

### DETAILED DESCRIPTIONS

Exemplary embodiments related to the present invention will be explained below in detail with reference to the accompanying drawings.

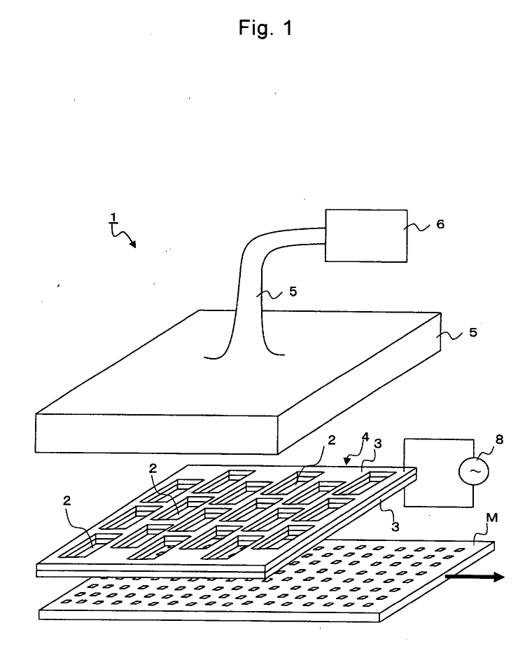

FIG. 1 is a schematic perspective view of a plasma processing apparatus centering around a reaction chamber according to one embodiment of the present invention. A plasma processing apparatus 1 includes an electrode unit 4, a gas inlet tube 5, a gas supply unit 6, and a power supply unit 8. The electrode unit 4 is configured such that a dielectric layer is provided on a surface of a metal substrate 3 having a plurality of through holes 2 formed therein, and such that a plurality of metal substrates 3 are superimposed so that the through holes 2 coincide with one another. The gas inlet tube 5 uniformly blows a surface treatment gas or a reactive gas against the through holes 2. The gas supply unit 6 supplies the gas to the gas inlet tube 5. The power supply unit 8 applies a voltage among the metal substrates 3.

As shown in FIG. 1, the plasma processing apparatus 1 is structured to inject a plasma from a lower surface of the electrode unit 4 toward a processing target member M. Although the real through holes 2 are very small, they are shown large in FIG. 1 for the sake of convenience.

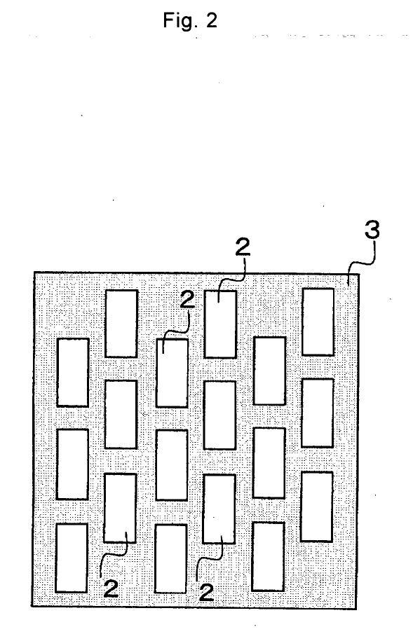

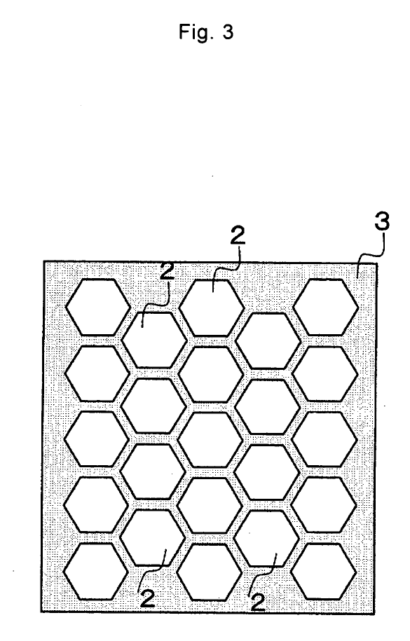

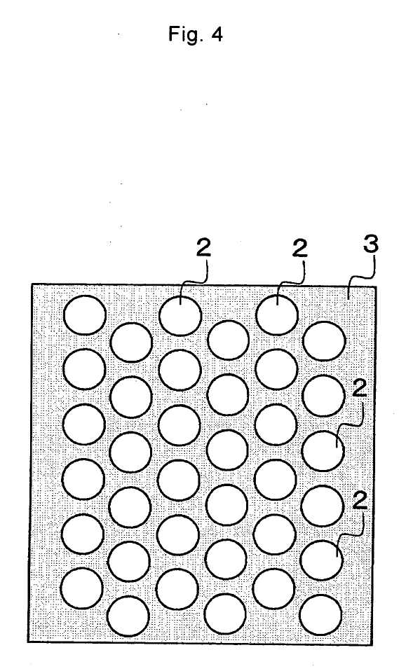

An electrode structure will first be explained. FIGS. 2 to 5 are plan views of examples of the electrode employed in the plasma processing apparatus 1 according to this embodiment. The through holes 2 can be in the form of a mesh in which the holes are arranged two-dimensionally (laterally and longitudinally) at predetermined intervals as shown in FIGS. 2, 3, and 4, or can be slits arranged one-dimensionally (only in one direction) at predetermined intervals as shown in FIG. 5.

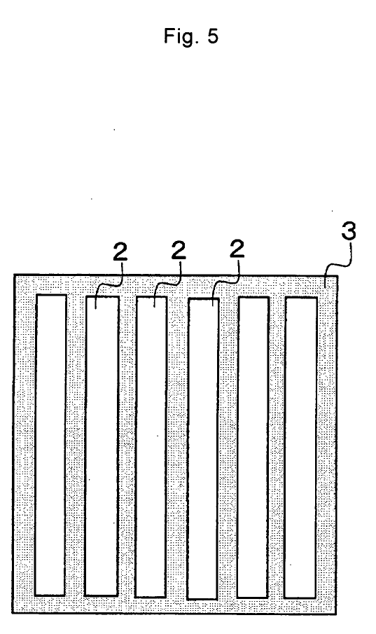

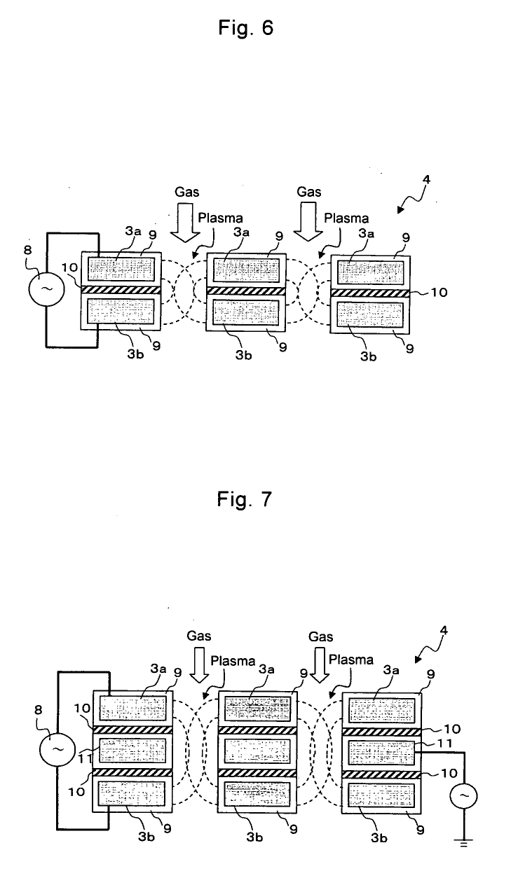

FIG. 6 is a sectional view of the electrode unit 4 of the plasma processing apparatus 1 according to this embodiment. As already explained, the electrode unit 4 includes the through holes 2 and is configured such that an upper metal substrate 3a covered with a dielectric layer 9 and a lower metal substrate 3b covered with another dielectric layer 9 are bonded to each other by a bonding layer 10.

The plasma processing apparatus 1 applies a voltage to the upper metal substrate 3a and the lower metal substrate 3b while supplying the gas to the through holes 2 from above, thereby generating a plasma. As the bonding layer 10, a low melting point glass is normally used. However, when the glass is used as the dielectric layer 9, the substrates 3a and 3b can be thermally bonded only by the dielectric layers 9. It is not, therefore, always necessary to provide the bonding layer 10.

As another embodiment of the plasma processing apparatus 1, a third electrode can be inserted between the upper and lower metal substrates 3a and 3b. FIG. 7 is a sectional view of the electrode unit 4 when the third electrode is additionally provided in the plasma processing apparatus 1 according to this embodiment.

As shown in FIG. 7, a third electrode 11 is inserted between the upper metal substrate 3a and the lower metal substrate 3b. As explained later, it is possible to control the discharge voltage applied to the upper metal substrate 3a and the lower metal substrate 3b to be reduced and to control a discharge generated therebetween to be turned on and off according to a voltage applied to the third electrode 11. In addition, since a discharge length itself can be increased, plasma generation efficiency can be enhanced.

A solid-state dielectric that forms the dielectric layer 9 is required to have such characteristics as a high insulating property, a high dielectric constant, a high secondary electron emission coefficient, a high sputtering resistance, and a high heat resistance.

The reason for using the dielectric having the high insulating property is as follows. When the dielectric has a low insulating property, it is subjected to dielectric breakdown by the voltage applied to the electrode and an arc discharge is generated. The dielectric having a dielectric breakdown voltage equal to or higher than 100 volts is preferably used.

The reason for using the dielectric having the high dielectric constant is as follows. When the dielectric having the high dielectric constant is used, then a wall voltage opposite in polarity to a voltage of an external electrode is induced during the discharge and a temporal increase of a discharge current can be suppressed. It is, therefore, possible to maintain the discharge stable. The dielectric having a dielectric constant equal to or higher than three is preferably used.

The reason for using the dielectric having the high secondary electron emission efficiency is that a discharge firing voltage can be reduced. The dielectric having a secondary electron emission efficiency equal to or higher than 0.1 relative to gaseous ions higher in ionization energy than argon (Ar) is preferably used.

The reason for using the dielectric having the high sputtering resistance is to reduce damages of the dielectric layer by an ion bombardment in a plasma.

The reason for using the dielectric having the high heat resistance is as follows. During a surface treatment or film deposition, the electrodes are often heated so as not to attach a gaseous component to the electrodes. The dielectric having a heat resistance equal to or higher than 200° C. is preferably used.

It is necessary to set a thickness of the dielectric layer 9 in view of a combination of the insulating property, the dielectric property, and the sputtering resistance. When the thickness is small, the insulating property and the sputtering resistance of the dielectric layer 9 are deteriorated but the dielectric property thereof is improved. Conversely, when the thickness is large, the insulating property and the sputtering resistance are improved but the dielectric property is deteriorated. Basically, it is important to form the dielectric layer 9 high in insulating property and sputtering resistance even if being thin, on the metal substrate 3 so as to be able to improve the dielectric property. In addition, a film thickness of the dielectric layer 9 is 0.1 micrometer to 100 micrometers.

Materials that generally satisfy these requirements include oxides mainly consisting of SiO₂, Al₂O₃, MgO, ZrO₂, TiO₂, Y₂O₃, PbZrO₃—PbTiO₃, BaTiO₃, and ZnO, respectively. Needless to say, a compound oxide obtained by mixing two or more of them or an oxide in a simple phase by completely subjecting one of these material to a solid-solution heat treatment can be used as the material for the dielectric layer 9. Alternatively, an alkaline or alkaline-earth element can be added to one of these oxides to form a glassy material.

Furthermore, a material high in insulating property and dielectric constant can be used to form a lower layer, a material high in secondary electron emission coefficient can be used to form an upper layer, and each metal substrate 3 can be covered with these upper and lower layers. For example, an SiO₂ material and an MgO material can be used for the lower layer and the upper layer, respectively.

A material for the metal substrate 3 is preferably close to the oxide in thermal expansion coefficient. Specifically, a material having a thermal expansion coefficient in a range between 1×10⁶/° C. and 12×10⁶/° C. (30° C. to 300° C.) is appropriate.

As the material that exhibits this characteristic, an Fe—Ni alloy containing 36 to 55% by mass of Ni relative to Fe can be used. Examples of a typical metal material include a 36% Ni—Fe alloy, a 42% Ni—Fe alloy, a 47% Ni—Fe alloy, and 50% Ni—Fe alloy. Alternatively, an Fe—Ni—Cr alloy such as 42% Ni-6% Cr—Fe alloy or an Fe—Ni—Co alloy having a part of Ni substituted for 10% or less Co can be used. Needless to say, an element that can intensify strength can be appropriately added to the alloy.

A method for applying the voltage to the metal substrates 3 will be explained. Since each metal substrate 3 is covered with the solid-state dielectric, a DC current is not carried between the metal substrates 3. For this reason, the plasma processing apparatus 1 according to this embodiment supplies a voltage that relatively forms alternating current between the two metal substrates 3. A waveform of the voltage can be a sinusoidal form, a rectangular pulse form, or a sawtooth form. While a peak value of the voltage depends on the type of the gas or on the pressure, it is approximately between 100 volts and 10 kilovolts. While an average current depends on an electrode area, it is approximately between 1 milliamper and 100 ampers. In addition, a frequency of the power can be in an arbitrary band from a low frequency such as 1 kilohertz to 1,000 megahertz to a very high frequency range.

As shown in FIGS. 6 and 7, in the electrode arrangement according to this embodiment, surfaces of the dielectric layers 9 are charged by discharge current similarly to a dielectric barrier discharge, and a charging voltage is negatively fed back to the applied voltage. Current concentration is, therefore, automatically suppressed. In addition, a size of the through holes 2 is selected between 1 micrometer and 10 millimeters to correspond to the type of an operating gas and the pressure, whereby stable operation can be ensured in a uniform glow discharge mode. The size of the through holes 2 can be appropriately selected according to a shape of the through holes such as one side, a diagonal line, a diameter, a longer diameter, and a shorter diameter.

The reactive gas used for the surface treatment will next be explained.

The “surface treatment” means in this embodiment to transform surface properties of the processing target member M by plasma. For example, the surface treatment includes a treatment for making the surface of the processing target member M hydrophilic or water-repellent, a treatment for decomposing and removing contaminations or foreign matters on the surface of the processing target member M, and an etching processing.

To make the processing target member M hydrophilic, gas containing oxygen or an oxygen compound, nitrogen or a nitrogen compound or the like can be used. To make the processing target member M water-repellent, gas containing fluorine, a fluorine compound or the like can be used. To decompose and remove the contaminations or foreign matters on the surface of the processing target member, the gas needs to be selected according to types of the contaminations or foreign matters. When the contaminations or foreign matters are organic matters, gas containing oxygen or the oxygen compound can be used. To etch the processing target member M, halogen gas or the like can be used.

The gas used for the film deposition will next be explained.

Examples of the reactive gas for applying the plasma film deposition method according to this embodiment to a chemical vapor deposition (hereinafter, “CVD”) include gases obtained by evaporating an organic metal compound, a metal hydrogen compound, a metal halogen compound, a metal alkoxide and the like and C-containing gases.

Among other things, the gas obtained from the metal alkoxide is preferably used since low cost process can be realized. For example, when an SiO₂ film is to be formed, tetraethoxysilane can be used. When an Al₂O₃ film is to be formed, butoxyaluminum can be used. When a ZrO₂ film is to be formed, propoxyzirconium can be used. When an MgO film is to be formed, magnesium acetylacetonate can be used. When a TiO₂ film is to be formed, propoxytitanium can be used. When an Si film is to be formed, SiH₄ or the like can be used, and a C film is to be formed, CH₄ or the like can be used.

Since one of these surface treatment gases and reactive gases diluted with gases such as N₂, O₂, H₂, Ar, He, Ne, Ar, Kr, or Xe is more economical than the gases used solely, the surface treatment gas or the reactive gas can be mixed with the dilution gas.

The “pressure near the atmospheric pressure” according to this embodiment means pressure from 13 to 200 kilopascals and is referred to as “normal pressure”. More preferably, the normal pressure is about 100 kilopascals. This pressure is a gas pressure in a state in which the surface treatment gas or reactive gas is mixed with the dilution gas. A partial pressure of the sole surface treatment gas or reactive gas can be lower than about 100 kilopascals.

In this embodiment, the gas is supplied into the through holes 2 of the metal substrates 3. A gas supply mechanism can be such that the gas is passed through the gas inlet tube 5 using the gas supply unit 6 and then introduced to the upper metal substrate 3a. Depending on usage, the gas supply mechanism can include a degassing equipment (for example, a vacuum pump).

In this embodiment, an appropriate distance between the lower metal substrate 3b and the processing target member M is 1 millimeter to 10 centimeters in view of an effective lifetime in a gas phase of a reactive precursor involved with the plasma processing. The distance is more preferably about 1 to 10 millimeters. A heating temperature of the processing target member M and the metal substrates 3 is preferably in a range between the room temperature and 500° C., more preferably between the room temperature and 350° C.

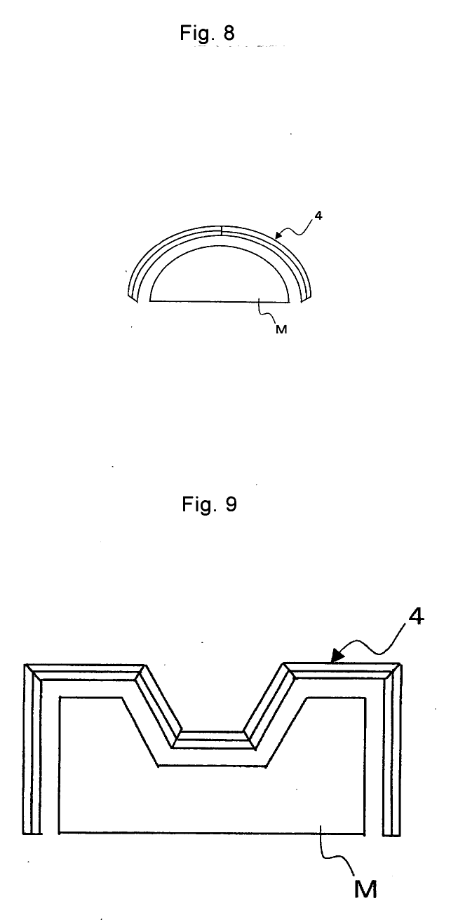

In the above explanation, the processing target member M is assumed as a flat member. However, the present invention is not limited to the flat processing target member M and this embodiment, therefore, characteristically has a high surface flexibility. FIGS. 8 and 9 are explanatory diagrams of configuration examples of the electrode unit relative to a curved processing target member M and an irregular processing target member M, respectively. As shown in FIGS. 8 and 9, the electrode unit 4 is formed to follow the surface form of the processing target member M, thereby making it possible to perform a plasma processing even on a member in a complicated form.

### FIRST EXAMPLE

The embodiment will be explained in more detail with reference to examples.

As the material for the metal substrates, an Fe-47 weight % Ni alloy having the thermal expansion coefficient of 8.3×10⁻⁶/° C. is used to form the metal substrates each having a thickness of 0.5 millimeter, a width of 800 millimeters and a length of 800 millimeters. A spray wet etching is performed to spray an FeCl₃ aqueous solution from a nozzle onto the metal substrates to form many through holes and thereby provide metal substrates for electrodes. The size of the through holes is such that a width is 500 micrometers and a length is 1000 micrometers, and meshed metal substrates are formed (see FIG. 2).

A two-layer oxide film having an Al₂O₃ lower layer (at a thickness of 2.1 micrometers) and an MgO upper layer (at a thickness of 0.9 micrometer) is formed on the surfaces of each metal substrate, thereby providing electrode substrates. A low melting point glass having a softening point of 430° C. is inserted between the two electrode substrates, and the glass and the electrode substrates are thermally bonded, thereby providing the electrode unit. The two electrode substrates are bonded so that positions of their through hole coincide with one another. The sectional structure is as same as that shown in FIG. 6.

As the processing target member M, a metal partition for a plasma display (PDP) (hereinafter, “PDP metal partition”) including many through holes is used. The PDP metal partition consists of an Fe-47 mass % Ni alloy and the size thereof is such that a thickness is 0.2 millimeter, a width is 700 millimeter, and a length is 1200 millimeters.

In an experiment, the air at a pressure of 100 kilopascals is supplied from above the electrode substrates toward the through holes (see FIGS. 1 and 6). Voltage driving conditions are as follows. A rectangular wave pulse (a pulse width of 1 to 10 microseconds and a peak voltage of 300 to 500 volts) is alternately applied to the upper and lower electrode substrates to drive the electrodes. It can be then confirmed that plasma is in a glow discharge plasma state.

When the PDP metal partition is processed using this plasma, it is confirmed that a resin resist residue adhering to a surface of the partition is decomposed and removed and that the surface is cleaned. When the surface of the PDP metal partition thus processed is observed by a scanning electron microscope (SEM), it is confirmed that no resist residue is present on the surface.

Thereafter, the reactive gas of tetraethoxysilane is diluted with N₂ gas and O₂ gas and the gas mixture is supplied to the through holes of the electrode substrates so as to form a film on the resist-removed PDP metal partition. At this time, a peak value of an applied pulse voltage is adjusted to fall between 300 and 800 volts. Furthermore, a temperature of the processing target member and that of the electrode substrates are set to 300° C. and 250° C., respectively. After the processing, it is confirmed that an SiO₂ amorphous film is formed on the PDP metal partition.

When the dielectric layers on the surfaces of the metal substrates are subjected to the surface treatment and the film depositing using SiO₂, Al₂O₃, MgO, ZrO₂, or Al₂O₃+TiO₂, the same result is obtained. The result is shown in Table 1 below.

TABLE 1

| | | Film | Plasma | | Film |
|---|---|---|---|---|---|
| | | thickness | discharge | Surface | formation |
| No. | Composition | (μm) | state | treatment | processing |
| 1 | Al₂O₃ + MgO | 2.1 (lower | good | good | good |
| | | layer) + 0.9 | | | |
| | | (upper layer) | | | |
| 2 | SiO₂ | 2.1 | good | good | good |
| 3 | Al₂O₃ | 2.0 | good | good | good |
| 4 | MgO | 2.1 | good | good | good |
| 5 | Al₂O₃ + TiO₂ | 2.1 (lower | good | good | good |
| | | layer) + 0.9 | | | |
| | | (upper layer) | | | |

### SECOND EXAMPLE

Three metal substrates similarly to those according to the first example are manufactured, and then thermally bonded to provide an electrode unit. Similarly to the first example, the dielectric layer is the two-layer oxide film of Al₂O₃+MgO. The sectional structure is as same as that shown in FIG. 7.

An experiment is conducted using the same PDP metal partition as that used in the first example as the processing target member M.

Similarly to the first example, the rectangular pulse is alternately applied to the upper and lower electrode substrates (main electrodes), a pulse voltage of about 50 to 200 volts is applied to the metal substrate (third electrode) as the intermediate layer, and the timing of the latter application is changed. If so, it is confirmed that a discharge maintaining voltage between the main electrodes can be reduced within a certain range. Particularly when rising of the pulse voltage applied to one of the main electrodes coincides with that of the pulse voltage applied to the third electrode, a reduction in the discharge sustaining voltage reaches a maximum. In addition, when the pulse voltage having a certain peak value is applied to the third electrode at the rising of the pulse or an intermediate timing, it is confirmed to be difficult to sustain the discharge.

It is thus confirmed that the discharge can be controlled to be switched on and off using this phenomenon and that this can be used for process control.

As can be seen, according to this embodiment, it is possible to provide the method and apparatus for plasma processing exhibiting high productivity and capable of generating the stable glow discharge plasma even at the pressure near the atmospheric pressure in a wide range, and capable of simultaneously processing the entire surface of the processing target even if the processing target is a metal member having a large area. Accordingly, productivity can be considerably improved in the surface treatment and the film depositing necessary for the steps of manufacturing a semiconductor or a display or steps of manufacturing constituent components thereof. Namely, according to the techniques disclosed in the Patent Literatures 1, 2, 5, and 6, the electrodes face with each other and when the metal processing target member is inserted between the electrodes, an arc discharge can be disadvantageously possibly generated between the processing target member and the electrodes. According to the technique disclosed in the Patent Literature 3, the size of the reaction chamber is restricted and it is often disadvantageously impossible to apply the processing to the processing target member having a large area. According to the technique disclosed in the Patent Literature 4, high power is required and productivity is disadvantageously deteriorated when the processing is applied to the processing target member having a large area. On the contrary, according to this embodiment, such disadvantages can be overcome.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A plasma processing method using an apparatus including an electrode unit configured by providing a dielectric layer on a surface of a metal substrate having a plurality of through holes and by superimposing a plurality of the metal substrates so that the through holes coincide, the method comprising:
a gas supply step of supplying a predetermined gas at a pressure near an atmospheric pressure into the through holes;
a voltage application step of applying a voltage between the metal substrates to transform the gas within the through holes into a plasma; and
a processing step of processing a processing target member arranged near the electrode unit to face the electrode unit.

2. The method according to claim 1, wherein
at the gas supply step, a surface treatment gas is supplied, and
at the processing step, the processing target member is subjected to a surface treatment.

3. The method according to claim 1, wherein
at the gas supply step, a reactive gas is supplied, and
at the processing step, the processing target member is subjected to a film deposition.

4. The method according to claim 1, wherein
the dielectric layer mainly consists of at least one oxide selected from a group consisting of SiO₂, Al₂O₃, MgO, ZrO₂, TiO₂, Y₂O₃, PbZrO₃—PbTiO₃, BaTiO₃, and ZnO.

5. The method according to claim 1, wherein
each of the metal substrates consists of an Fe—Ni alloy containing 36% to 55% by mass of Ni.

6. An apparatus for plasma processing comprising:
an electrode unit configured by providing a dielectric layer on a surface of a metal substrate having a plurality of through holes, and by superimposing a plurality of the metal substrates so that the through holes coincide with one another;
a gas supply unit that supplies a surface treatment gas or a reactive gas to the through holes; and
a voltage application unit that applies a voltage between the metal substrates.

7. The apparatus according to claim 6, wherein
the dielectric layer mainly consists of at least one oxide selected from a group consisting of SiO₂, Al₂O₃, MgO, ZrO₂, TiO₂, Y₂O₃, PbZrO₃—PbTiO₃, BaTiO₃, and ZnO.

8. The apparatus according to claim 6, wherein
each of the metal substrates consists of an Fe—Ni alloy containing 36% to 55% by mass of Ni.

9. The apparatus according to claim 6, wherein
at least three metal substrates are superimposed, and the voltage application unit is configured to apply a voltage between the both end metal substrates, and
the apparatus further includes a third electrode control unit that applies a voltage for controlling a discharge in the through holes between the metal substrates, to the intermediate metal substrate.
